(19) United States
(12) Patent Application Publication
(10) Pub. No.: US 2004/0165735 A1
(43) Pub. Date: Aug. 26, 2004

(54) Self-calibration of array microphones

(75) Inventor: Martin Opitz, Wien (AU)

Correspondence Address: Friedrich Kueffner, Suite 910, 317 Madison Avenue, New York, NY, 10017, US

(73) Assignee: AKG Acoustics GmbH

(21) Appl. No.: 10/786,494

(22) Filed: Feb. 25, 2004

(30) Foreign Application Priority Data
Feb. 25, 2003 (EP) 03450050.4

(51) Int. Cl. H04R 29/00; H04R 3/00; H03G 3/00

(52) U.S. Cl. 381/92; 381/58; 381/122

(57) ABSTRACT

The invention relates to an array microphone with several individual microphones (1-4) connected with a signal processor (11) that for each individual microphone, comprises at least one digital filter, in particular for voice recognition.

The invention is characterized in that at least one loudspeaker (5) is provided, which is arranged in the acquisition area of each of the individual microphones (1-4), in that an electronic circuit is provided, which applies a signal to the loudspeaker (5) in such a manner that it emits a predetermined periodic noise signal, and in that the signal processor (11) evaluates the response signals coming from each of the microphones and/or from each of the digital filters as a response to the reception of the periodic noise signal.

Speech is becoming increasingly important as a means of communication between man and machine. Because most applications require natural speech, the microphone, which receives the speech signal, is not immediately in front of the speaker's mouth; rather, it is at a certain distance from the person, which in many applications is continuously changing. In passenger cars, for example, array microphones are used, on the one hand, as a natural-speech microphone for telephone conversations and, on the other hand, with systems that are operated by voice recognition, such as, navigation systems.

However, one limiting factor in speech recognition is that the speech level, and thus the signal/noise ratio, decreases with an increasing distance between the sound source and the microphone. In environments with undesired interfering noise sources, such as cockpits in airplanes, motor vehicles, conference rooms, lecture halls and surgery rooms, it is therefore necessary to take measures to suppress the noise. So-called beam forming methods offer efficient solutions to these problems. Here, several microphones, so-called microphone arrays, are used for the reception of the speech signal. As a result of the spatial arrangement of the individual microphones with reference to the sound source, as well as due to the filtering and combination of the individual microphone signals, a spatial directive effect is produced. Signals that are incident on the microphone array from the useful signal direction are transferred essentially without distortion, while signals from other directions can be strongly suppressed. Adaptive beam-formers here can be adapted to movable interference sources that change over time, for example, the start phase, flight phase, landing phase, etc., of a plane. One prerequisite for the operation of a beam-former is to localize the speaker in the space, for example, several pilots in a cockpit, and, optionally, to follow their movements. To achieve additional high directive effects, the filters in the beam-former must in part generate large amplifications. However, as a result, the sensitivity is increased with respect to individual microphones of the microphone array, which are affected by error. Particularly serious interfering effects can result from tolerances in the transmission properties of the individual microphones, such as the frequency range, directive effect, sensitivity, etc.

Thus, array microphones are capable of the targeted resection of sound sources and speakers, short of the useful signals, and they can suppress interference signals, such as ambient noise or the generation of echo. Thus, for example, WO 99/39497 shows one possibility for the acoustical suppression of echoes for natural-speech installations. By means of this invention, undesired echoes that occur with natural-speech installations are to be eliminated. Here, an acoustical signal, a so-called pseudo noise signal, is emitted by a loudspeaker in the direction of at least two microphones. Adaptive filters, preferably FIR (finite impulse response) filters, are used to reshape the pseudo noise signal of a PN generator, by means of algorithms that use a set of filter coefficients. The response signals of the microphones are combined by addition of the inverted output signals of the corresponding adaptive filters. Using LMS (least mean square) algorithms, the output signals of the adding device, that, is the combined signal, is adjusted such that its energy is minimal. For this purpose, the filter coefficients are changed.

In an additional calibration step, now with fixed filter coefficients, a test signal, for example, a human voice, is applied to the microphones. The output signals of the different addition devices are combined and converted in a beam-former. The so-generated signal is compared with the original, near “unbiased,” signal of the microphones. The combined signal that has been formed is led to the beam-former, where it is used to adapt the beam-former in such a manner that the signal/noise ratio is maximized. After completion of the adaptation of the beam-former, that is, in the operational state, the filters are again switched to the adaptive mode, and instead of a PN (pseudo noise) generator, the signal of a user who is talking at the other end of the line is connected with the adaptive filters. By this method, an artificial echo is generated, which substantially corresponds to the one recorded by the microphones, and which can be subtracted from the recorded echo.

Array microphones essentially consist of an arrangement of individual microphones, which are interconnected by signal technology. In the arrangement of the microphones, one can distinguish, in principle, microphones that are in a one-, two-, and three-dimensional arrangement. In the one-dimensional arrangement, the microphones are strong along a line, for example, a straight line or an arc of a circle. When using microphones with a spherical directive characteristic, the direction of the individual microphones is not essential because they only function as pressure receivers and their effect in space is therefore undirected. When gradient microphones are used, the orientation of the individual microphones is crucial: The overall directive characteristic and thus the overall bundling of the array microphone is produced by the combination of the directive characteristics of the individual microphones, using the algorithm, which is described in further detail below, by means of which the microphone signals are processed together.

One distinguishes two types of one-dimensional array microphones: broadside array microphones and endfire array microphones. They differ in the preferred direction of incidence of the sound with respect to the arrangement of the microphones: For endfire array microphones, the preferred direction of incidence of sound is in the longitudinal direction of the microphones, that is, directions of incidences of sound with θ=0°. For broadside array microphones, the preferred direction of incidence of sound is θ=90°. The mutual intervals between the microphones can be constant or can differ from each other. In the second case, for different frequency ranges, different groups of microphones for the beam-forming are used, as described in M. Brandstein, D. Wards (Editors), Microphone Arrays, Springer Verlag, 2001.

The connection, by signal technology, of the individual microphones can be analog or digital. Below, the digital implementation will be considered. The individual microsignals are digitized using A/D converters (analog/digital converters) and they are led to a signal processing unit. The signal processing unit uses an appropriate algorithm (key word “beam-forming”) on the microphone signals. With the use of this algorithm, the bundling degree of the microphone is increased and lateral sound sources are suppressed. A good review of array microphones can also be found in M. Brandstein, D. Wards (Editors), Microphone Arrays, Springer Verlag, 2001 and in the literature cited therein.

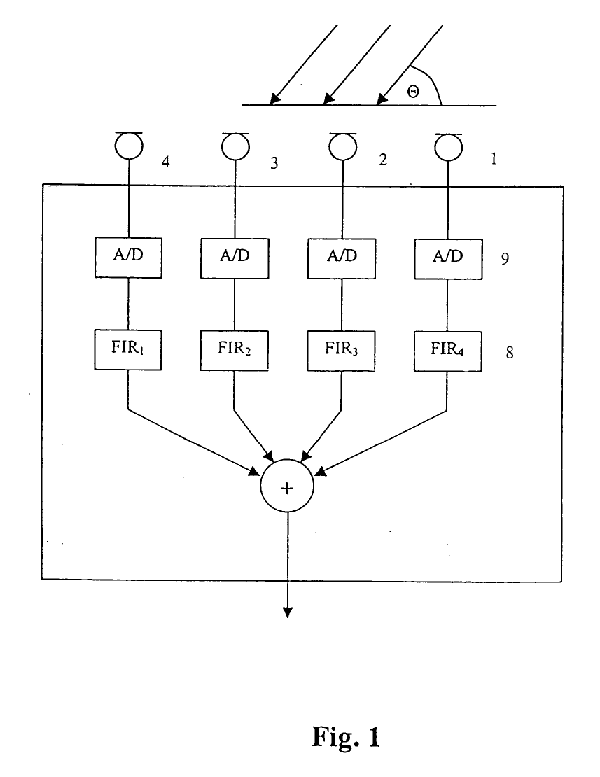

Sets of filter coefficients are a component of the algorithm, and they are characteristic for the arrangement, the type, sensitivity, and characteristics of the microphones used, as well as the acoustical environment and the locations of the sound sources. Different properties of the different microphones, as produced, for example, by finishing dispersions, aging effects, etc., can be taken into account in these sets of filter coefficients. A frequently used film structure is described in the literature under “Filter and Sum Beam-former” (see, for example, M. Brandstein, D. Wards (Editors), Microphone Arrays, Springer Verlag, 2001, page 159). Here, the individual microphone signals are filtered, after the analog/digital conversion, with appropriate FIR filters (finite impulse response filters) and then added. FIG. 1, which is representative of the state of the art, shows an embodiment example with 4 microphones.

FIG. 1 shows a simple microphone array with identical distances d between the individual microphones. The incident angle of sound, θ, is expressed with reference to the longitudinal axis of the microphone array. The incident sound wave arrives after different travel times at the individual microphones of the array. The travel time differences correspond to the path differences d*cos(θ). The FIR filters 8 FIR₁ to FIR₄ shown in FIG. 1 contain filter coefficient sets that correspond to frequency-dependent differences in amplitude and phase. After the filtering, the signals are added (filter and sum beam-former). Due to the mentioned differences in amplitude and phase, the sound waves arriving at a certain direction of incidence are amplified by constructive overlay, and sound waves coming out of the other sound incidence direction are weakened by destructive overlaying. As the simplest special case, one can imagine the FIR filters 8 FIR₁ to FIR₄ to be so-called all-pass filters, all presenting the same frequency-independent delay. In this case, sound waves having an angle of incidence θ=90° are amplified, and sound waves from other directions of incidence are weakened, that is, the setup is that of a so-called broadside array.

The above-mentioned filter coefficient sets are calculated for a fixed predetermined standard situation, in many applications, and they are used at constant magnitudes during the operation of the array microphone.

The verification of individual microphones in the array occurs in such a manner that the current uptake of the individual microphones is checked during the installation or during servicing. The value of the current uptake is checked to determine whether it is between two predetermined limit values. In this manner, one can establish whether the individual microphone in principle is capable of operating. Nothing more happens.

A method and a device to check the function of individual microphones that are not part of an array microphone are known from EP 0 268 788. A microphone is housed in a sensor device together with test loudspeakers. A sinusoidal test signal from a generator is applied to the series-connected test loudspeakers. In a signal correlator, a measurement is made of the phase differences between the signal that has been converted by the microphone to be tested and the original generator signal. The output voltage of the signal correlator, which corresponds to a certain phase difference between the two signals, is compared to a threshold value S in a threshold value comparator. Depending on whether the phase difference exceeds the threshold value S or not, a bad or good signal is transmitted to a central evaluation location. By this method, it is only possible to measure the functional capacity of a microphone that is placed in sound measurement installations. Only a phase measurement is carried out. Important parameters and characteristic values that are inherent in a microphone, such as the frequency range or directive characteristic, cannot be checked by this method. In the end, the measurement of the phase difference only results in the generation of a bad or good signal.

In array microphones, in connection with the failure of one of the microphones, additional problems arise, which cannot occur at all with individual microphones.

One of these problems concerns the failure of an individual microphone. This can strongly decrease the bundling degree of the entire microphone and change the directive characteristic in an undesired manner. The user observes a worsening of the function controlled by the array microphone, without being able to locate the precise cause, that is, the voice recognition suddenly works only poorly, and the speaker is poorly understood when telephoning.

In general, the poor performance results can have different causes, which do not have to be connected with the array microphone. For example, the GSM transmission line used during the telephoning can be defective. To allow a diagnosis of errors, it is therefore essential to know whether the array microphone is at least fully functional as a partial system. According to the state of the art, the current uptake of the microphone can only be observed in the laboratory or during a service procedure.

An additional problem is of a rather pernicious nature: As a result of the dispersions of the properties of the individual microphones during the manufacture, or as a result of different courses of the aging process or different reactions to changing environmental conditions, the directive and frequency characteristics of the individual microphones can strongly differ from each other. As a result, the above-mentioned algorithms can no longer work as desired for the signal processing.

US 2002/0146136 A1 discloses a method for the calibration of an acoustic converter, which is not part of an array microphone, in particular for mobile telephones. This calibration makes it possible for an electronic unit to deliver the desired amplitude and frequency responses, independently of the operative differences that can occur between microphone and loudspeaker components. Here, a signal of a pseudo noise generator is applied through a filter to an external loudspeaker. The response signal of the microphone, in a DSP (digital signal processor), is filtered or converted using filter coefficients that reflect the inverse channel pulse response h of the arrangement; after filtering, it is compared with a “desired” signal obtained directly from the pseudo noise generator. The difference between the two signals, the so-called error signal, serves the function of changing the filter coefficient of the DSP. The filter is an adaptive type, that is, the filter coefficients are iteratively determined. They converge to a limit value, which results in the smallest possible error signal.

The drawback of this method is that the converter is calibrated in a test environment and not at the site of use itself. The external test loudspeaker is again removed, then the cell telephone is released for use. In actual use, as a function of the acoustic surrounding, it is possible that the filter coefficients determined by an iterative method do lead to nonconverging consequences or undesired instabilities. This method therefore does not take into consideration the continuously changing environment. Other important parameters and properties of the microphone in itself can also not be determined by this method. The loudspeaker, which emits the test signal, is not checked prior to the calibration process to determine its ability to function, for example, the size of its impedance, with such an omission resulting in error sources. Moreover, an extremely expensive arrangement with a loudspeaker, filter, and a delay circuit is required. By such an external arrangement, the distance between the microphone of a cell phone and the test loudspeaker is not unequivocally defined. Different distances lead to different filter coefficients.

An array microphone, which in its totality cannot be simply treated as the sum of its individual microphones, requires an entirely different testing from that of a single converter. Thus, during the installation of an array microphone, for example, in a vehicle cabin, the acoustic conditions are completely different compared to the test laboratory during development. Reflections, scattering, and interference due to multiple sound paths influence array microphones in a completely different manner than an individual microphone. In particular, the directive characteristic and the bundling degree of the array microphone can dramatically change to the detriment of the user. Factors such as dust deposition on the membrane, changes in the polarization voltage, and similar factors, in the case of individual microphones, merely produce a slightly softer or duller output signal. In contrast, in array microphones, the same factors cause a change in the overall microphone characteristic, and they may even make the microphone unusable. The false polarity of an individual microphone, as a component of an array microphone, represents the worst case, where signals from the useful signal direction are largely suppressed.

Similar changes in the microphone characteristics occur when the number and distribution of the persons in the car change, when a sliding roof or a window is opened or closed, etc. Furthermore, problems associated with a test loudspeaker must be taken into consideration when calibrating microphones. If an acoustic test signal is emitted, the properties of the loudspeaker must be precisely known, in particular the magnitude of the impedance, to be able to use a predetermined, precisely defined signal.

U.S. Pat. No. 5,719,526 describes load monitoring, integrated in an amplifier to achieve a delimitation of the power output and to prevent damage to the load of a loudspeaker, for example. The load monitoring involves a current and voltage measuring device and a computer and control circuit, for example, a DSP that calculates the impedance of the load connected to the amplifier and the output power to be transferred from the amplifier to the load from the measured voltage and current values. The signal applied to the amplifier can either be an external audio signal, or it can originate from a test generator that is also integrated in the amplifier. Computer and control-circuit-generated control signals are used for the purpose of optionally changing the signal processing functions of the amplifier and the corresponding function parameters. This method for the determination of the transferred power is relatively involved, since it requires a current and voltage measuring device and an evaluation unit. In addition, no information on the properties of the loudspeaker can be obtained.

The objective of the invention is to eliminate the above discussed drawbacks and problems, at the very least to achieve a clear decrease in their effects, without the need to remove the array microphone from its intended site of use or the need for a complicated and thus expensive retrofitting.

This objective is achieved according to the invention by providing at least one loudspeaker arranged in the acquisition range of each of the individual microphones, by providing an electronic circuit applied to the loudspeaker in such a manner that it emits a predetermined periodic noise signal and in that the signal processor evaluates the response signals coming from each of the microphones and/or from each of the digital filters, as a response to the reception of the periodic noise signal.

The loudspeaker is either permanently integrated in the array microphone, or it is a component of a transportable test device. It is also possible to use loudspeakers that either are already present, or integrated, in the three-dimensional space in which the array microphone is used, for example, the loudspeakers of a car radio in the driver cabin or a loudspeaker that is intended specifically for the test.

The signal processor can be that of the array microphone or it can also be a part of the test device. If several loudspeakers are provided, it is not only possible to control the individual microphones, but a particularly precise control of the beam-forming is also possible.

The invention is explained below in greater detail in a description with reference to an example. In the drawings:

FIG. 1 shows a sketch of the principle of the arrangement and signal connection according to the state of the art,

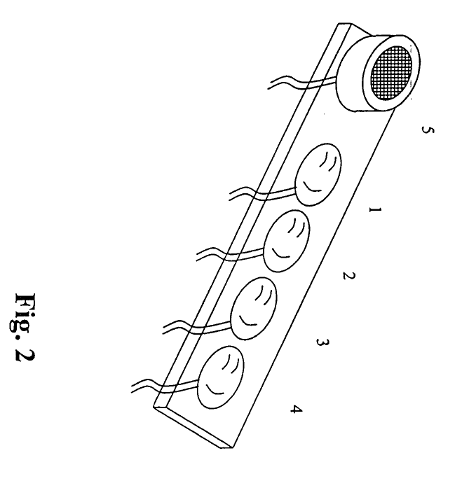

FIG. 2 is an embodiment example according to the invention with four microphones,

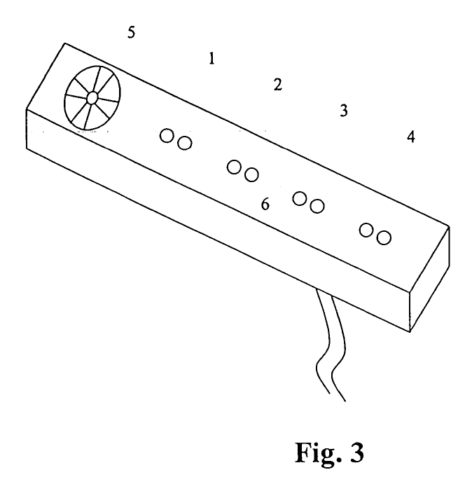

FIG. 3 is a variant of the embodiment of FIG. 2,

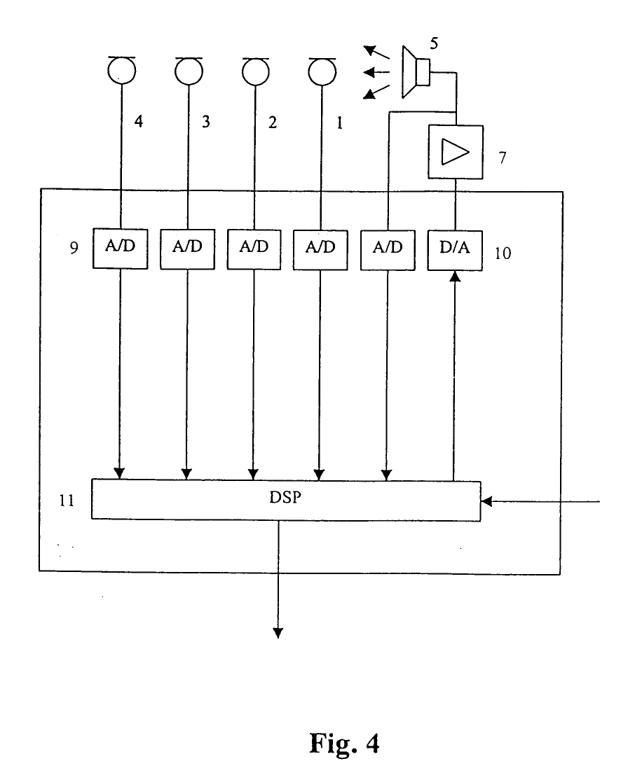

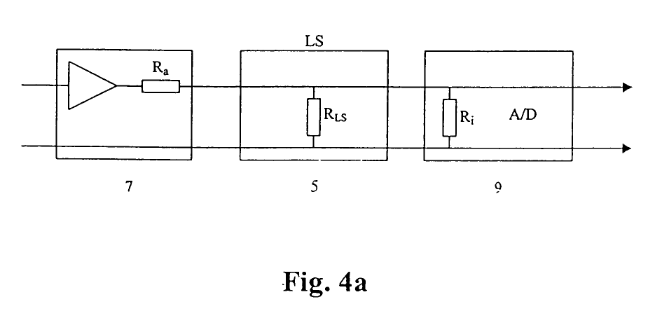

FIG. 4 is an embodiment example for measuring the loudspeaker impedance,

FIG. 4a is a wiring schemata for a method, and

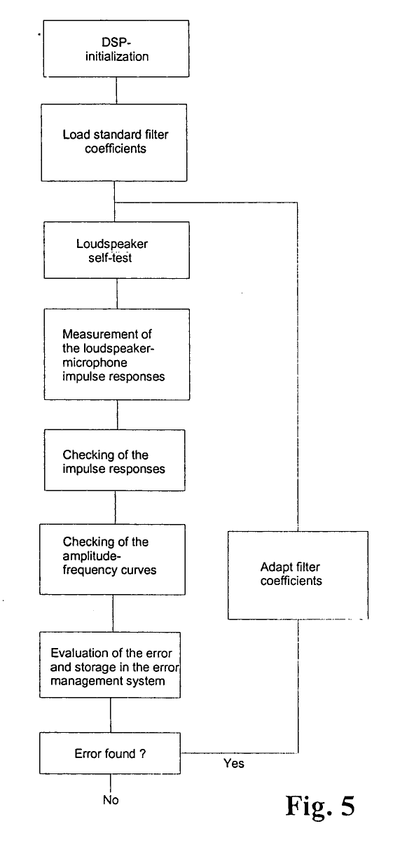

FIG. 5 is an embodiment example of the implementation of the method.

FIG. 2 shows an embodiment example of an array microphone according to the invention, consisting of 4 microphones 1-4. The distances of the individual microphones 1-4 are the same in this embodiment example. The loudspeaker 5 is arranged in such a manner that it acquires sound from all individual microphones 1-4, that is, a signal emitted by the loudspeaker 5 is received by all individual microphones. In variants, it is also possible to provide more than one loudspeaker, where it is not necessary that an individual microphone can receive the signals of all loudspeakers. It is only important that all individual microphones can receive a signal from a loudspeaker. The individual microphones 1-4 can be designed either as pressure receivers or gradient receivers. Naturally, the invention is not limited to 4 individual microphones.

FIG. 3 shows an additional embodiment of the invention. In principle, the example has the same structure as in FIG. 2, but all the acoustic converters are accommodated in a common housing 6. In this housing, it is also possible to accommodate electronic components, A/D and D/A converters 9, 10, digital filter 8, and signal processors 11. Only the openings, for speaking, of the microphones 1-4 are shown.

The device according to the invention can be structured as explained in greater detail below. The method according to the invention, which is carried out with the help of the loudspeaker and the signal processor, for example, as an acoustic self-test of the array microphone, can occur as follows:

A calibration loudspeaker 5—preferably a small loudspeaker based on the dynamic principle—is mounted in, on, or in the proximity of the array microphone, where the calibration loudspeaker has an acoustic connection to the individual microphones 1-4 of the array, in the sense that the loudspeaker's signal can be received by each of the individual microphones 1-4. For the case wherein only a single calibration loudspeaker 5 is used, an appropriate place for its positioning is in the middle of the microphone arrangement, or in the plane of symmetry of the microphone arrangement, where the sum of all the calibration loudspeaker-individual microphone paths is at a minimum. However, other loudspeaker positions are also conceivable, for example, at the edge of the array or at some distance therefrom, as in the represented embodiment examples. The calibration loudspeakers is connected to an amplifier.

FIG. 4 shows an array microphone according to the invention, in which the individual microphones are connected via A/D converter 9 to a digital signal processor 11. The digital filters, that change the individual microphone signal using appropriate filter coefficients, can be arranged between the individual A/D converters 9 and the signal processor 11. One digital filter 8 is then assigned to each individual microphone 1-4, as also shown in FIG. 1. The digital filters 8, preferably in the form of FIR filters, instead can also be integrated in the hardware in the digital signal processor 11, according to FIG. 4, so that the output of such an A/D converter 9 is led directly into the signal processor 11. For the filtering and evaluation, it is also possible to sequentially process the individual microphone signals from the signal processor 11, so that there is no longer a need for hardware between the individual microphones and filters, but the end result, namely signals that have been properly filtered, is the same. In the embodiment, it is also possible to provide more than one digital filter per individual microphone, for example, series or parallel switched filters.

The purpose of the self-test of an array microphone according to the invention in particular involves the verification of one or more of the parameters of the individual microphones 1-4 listed below:

The individual microphone is switched on,

the individual microphone has the correct polarity,

the individual microphone has the desired sensitivity,

the individual microphone presents the desired frequency course of the sensitivity,

the individual microphone does not present excessive distortion, and

the directed effect of the individual microphone.

Moreover, a self-test allows the determination of whether the individual microphones are in fact connected with the filters intended for them or whether connection errors occurred during the manufacturing process. For the purpose of verifying the individual microphone parameters, as listed above, the digital filters are programmed such that they represent an all-pass filter. The individual microphones can then reach the evaluation unit of the signal processor 11, in an “unbiased”, that is, in the original, state. As a result of the relative position of the individual microphones with respect to each other, it is also possible for differences in travel time to be recorded.

Besides the test of the function parameters of the individual microphones, another possibility consists of using the method according to the invention to verify whether the digital filters operate properly. This test controls whether the filter coefficients suitable for the application have been programmed in the digital filter, and whether the filter algorithms work properly or whether other errors are generated during the conversion of the digital signal.

The “unbiased” signal originating from an individual microphone as a response to the loudspeaker signal, or using a signal that has been filtered using filter coefficients, is compared in the output unit of the signal processor 11 with model signals that correspond to properly operating individual microphones 1-4 or properly operating filters. Independently of the deviation of this signal from the model signals, the value of individual filter coefficients or of all the filter coefficients of the set of filter coefficients is changed. It is preferred to have already fixed predetermined filter coefficient values stored in the different available filter coefficient sets, so that they can be used externally or in the signal processor 11. In the case of prestored filter coefficient sets based on laboratory measurements or theoretical calculations, there is no regulation circuit in the sense of an iterative process.

To illustrate, the following example is presented: A certain filter coefficient set generates a directive characteristic that directs a “beam” to the driver of a vehicle and that suppresses noise from other directions (superdirective beam-former). A filter coefficient set could also be intended to direct one “beam” to the driver of the vehicle and a second to the front seat passenger. The simplest case is that of a Delay & Sum Beam-former, represented in FIG. 1. In order to take into account changes in the acoustical environments (for example, open-closed sliding roof) in view of the directive characteristic of the array microphone, it is possible to program prestored filter coefficient values that fall between the two extremes—the Delay & Sum Beam-former and superdirective Beam-former—and which are calculated using the so-called Lagrange factors.

Before the beginning of the acoustic self-test, the calibration loudspeaker 5 is checked. In the process, a determination is made as to whether its electrical impedance is above a predetermined limit value. It is only if this condition is satisfied that the acoustic self-test of the microphone is started. The verification of the loudspeaker impedance can be carried out by applying the loudspeaker signal directly to an A/D converter 9. FIG. 4 shows an embodiment example of the measurement of the loudspeaker impedance, where the loudspeaker 5 is operated in parallel to the input impedance of an A/D converter 9. Should the ratio of the loudspeaker impedance to the input impedance of the A/D converter 9 deviate too much from the value of 1, then an additional preresistance can be switched before the loudspeaker.

The measurement of the loudspeaker impedance is carried out using a method that is known to technicians for measuring complex impedances. In the process, it is possible, for example, to apply a constant current source to the loudspeaker and to measure the voltage at the loudspeaker contacts.

A method according to the invention for determining the loudspeaker impedance is described below. The associated switching schemata is shown in FIG. 4a. Here a signal is sent through the D/A converter 10 to the output amplifier 7. This output amplifier has a defined output impedance Rₐ. The amplified signal reaches the loudspeaker 5 with the impedance R_{LS}, then the input of the A/D converter 9, which has a defined input impedance Rᵢ. Rₐ and R_{LS} form a voltage divider. The voltage is measured at the A/D converter and compared to a reference measurement, where, as impedance, a known reference impedance is used instead of the loudspeaker. The data of the reference measurement are determined only once and stored in a permanent memory (for example, in a ROM). From the two voltage values so determined, the unknown loudspeaker impedance R_{LS} can be determined. One can also use a measurement without a loudspeaker as a reference measurement, in which case the reference impedance has an infinite ohm value.

The evaluation of the microphon signals can be carried out in different manners. As suitable measurement signals, one can use sinusoidal signals, stochastic noise signals, or periodic noise signals, such as maximum cyclical noises. Several methods are described below as examples:

Method 1) In the simplest case, several sinusoidal signals with different frequencies are emitted in succession. The levels at the individual microphones are tested for the degree of being in tune, that is, to determine whether the measured voltages are within predetermined limits. From the results, one derives whether or not the microphone is capable of functioning.

Method 2) The loudspeaker sends out a periodic noise signal, for example, maximum sequence noises. By averaging the signal responses of the individual microphones, the signal/noise ratio is improved. From the averaged microphone signal responses, one can calculate the impulse responses of a given loudspeaker-microphone system using the so-called Fourier transformation (DFT). This method is analogous to the one found in the literature, for example, in Vorlander, M.: Anwendungen der Maximalfolgentechnik in der Akustik. Fortschritte der Akustik [Uses of the maximum sequence technique in acoustics. Progress in acoustics]—DAGA 94, pp. 83-102, for measuring loudspeakers and microphones. The impulse responses of the loudspeaker-microphone so measured are verified to determine whether their maximum is located within predetermined travel times.

The measured amplitude transfer functions are checked to determine whether they are within predetermined tolerance ranges. These amplitude transfer functions are a measure of the microphone's sensitivity. By comparing with a reference measurement, it is possible to determine the change in microphone sensitivity caused, for example, by aging or environmental influences.

The self-test is triggered, for example, by a control signal to the signal processing unit. The latter sends a measurement signal to the amplifier 7 and further on to the calibration loudspeaker 5. This measurement signal is recorded by the different microphones, then evaluated by an evaluation unit. From the recorded measurement signals, the above-mentioned microphone parameters can be obtained.

One embodiment variant of the acoustical self-calibration consists of sending out a measurement signal that is inaudible to persons in the vicinity, for example, to the occupants of passenger cars. The measurement signal here is sent out in an audio range with a low level. By averaging the recorded microphone signals over time, measurements can be carried out even at signal/noise ratios <0 dB, as is the case in room acoustics measurements, for example, in fully occupied concert halls, during the performance. It is only after averaging the signal responses that the correlated signal portions are amplified and the uncorrelated background noise is eliminated.

An additional embodiment variant consists of using several calibration loudspeakers; in this manner, the above-mentioned microphone parameters can be measured with greater precision and additional information on the directive effect of the microphones can be obtained.

Another embodiment variant of the acoustical self-calibration consists of carrying out the checking of the array in the ultrasound range, that is, using a frequency range that is inaudible to the user. For this purpose, the acoustical converters used must present, in a partial frequency range above 20 kHz, sufficiently high transmission factors.

Evaluation of the Observed Errors:

The errors that may have been determined in the evaluation procedure are preferably further processed in one or several of the following manners:

The error is stored in the error management system of the vehicle. At the next visit to a specialized shop, the defective microphone module can be replaced.

The error can be displayed in a vehicle, for example, in a system console by a control light, in a pop-up menu on the monitor of the vehicle computer, etc.

The error can be acoustically reported in the vehicle by issuing an appropriate warning through the car loudspeakers or the calibration loudspeaker of the array microphone.

The method according to the invention, disregarding the possibility of allowing the detection of a number of defects that to date, could not be determined; also presents the advantage that the measurements can be carried out while the microphone is operated. After a successful verification, it is possible to automatically display, for example, “microphone OK.”

Moreover, it is also possible to do justice to the above-mentioned second group of problems: For this purpose the acoustical self-test is carried out exactly as described above. The results of the recorded microphone signals are then used to make a new calculation of the above-mentioned coefficients and to implement them.

In this method according to the invention, the array microphones are automatically calibrated; the array microphones consists of several individual microphones 1-4, which are connected with a signal processor 11, which includes, for each individual microphone, at least one digital filter, where the signal processor 11 increases the bundling degree of the array microphone and suppresses lateral sound sources, by means of an appropriate algorithm applied to the individual microphone signals. In the process, filter coefficient sets, which are components of the algorithm, are applied to the digital filters, with the filter coefficient sets being characteristic for the arrangement, type, sensitivity, and characteristics of the individual microphones used, the acoustical environment, and the location of the sound sources. The signal processor 11 then proceeds to change the value of individual filter coefficients or of all the filter coefficients set, as a function of the deviation of the response signals from the model signals. The test can be repeated until the response signals are in the range of the model signals.

The type of adaptation of the filter coefficients can be carried out, for example, by taking into account, in the calculation of the filter coefficient sets, the age-caused change in the microphone sensitivity, which is determined by the above method. As a result, there is a compensation for changes in the microphone properties, in particular the sensitivity-frequency curve. The method is shown in the block schemata in FIG. 5.

It is possible for a person skilled in the art of electro-acoustics to carry out this adaptation without problems if he/she is aware of the invention. It is preferred to carry out the self-test, new calculation and implementation at regular time intervals. This also allows an improvement of the microphone bundling, because it can be used to react to changing environmental conditions such as to the opening or closing of windows, to persons entering or leaving a vehicle, to changes in the microphone properties due to changes in the environmental parameters such as air temperature, air pressure or air humidity, direct exposure of a part of the array microphone to the sun, with the resulting differences in the heating of the individual microphones, etc.

Finally, a concrete embodiment example is used to illustrate the signal evaluation:

If the loudspeakers are arranged clearly outside of the plane of symmetry of a linear array, as shown, for example, in FIG. 2 and FIG. 3, one has the possibility of carrying out the signal evaluation as described below. In the ideal case, the loudspeaker is mounted on the longitudinal axis of the microphone array outside of the microphone array itself. This method represents only an example of an evaluation; other arrangements are conceivable for a person skilled in the art who is aware of the invention. An all-pass filter with a travel time equal 0 ms is programmed into each filter of the individual microphone-filter pairs. A periodic noise signal, for example, a Schröder noise with 8192 scanning values and a scanning frequency of 44.1 kHz is applied to the loudspeaker. This corresponds to a period duration of 185.8 ms. The algorithm for generating Schröder noise is described, for example, in M. R. Schröder: Synthesis of Low-Peak-Factor Signals and Binary Sequences with Low Autocorrelation, IEEE transactions on information theory, pp. 85-89, Vol. 16, January, 1970. The chosen period duration must be louder than or equal to the reverberation time RT₆₀ of the measurement surrounding, for example, the cabin of a passenger car. This measurement signal is repeated, for example, 20 times, and acquired through the individual microphones and the associated filters. Here, the linearly sound pressure level measured at a 10-cm separation from the front edge of the loudspeaker is approximately 0.1 Pa.

The following evaluation is then carried out for each microphone-filter pair: The signal is averaged, excluding the first period, synchronously to the input signal. The purpose of this averaging is to increase the signal/noise ratio, and thus to increase the precision of the measurement. Environmental noise, such as noise components of the microphone, the loudspeaker, and the participating amplifiers, is suppressed by the averaging. The first period has to be excluded, because the first period contains a time section with uncorrelated signals due to the ground noise delay that always exists.

The averaged signal response is subjected to inverse discrete Fourier transformation (IDFT) and the spectrum so obtained is divided by the IDFT of the excitation signal. The result then is the transfer function of the entire electroacoustic four-pole loudspeaker-microphone-filter.

The amount of the transfer function must, in the case of a properly operating individual microphone, with a properly operating filter, must be within predetermined tolerance ranges.

This allows a first verification. Here, the levels of the transfer function of more remote microphones must be lower than those of the microphones located closer to the loudspeaker.

The phase of the transfer function can be evaluated and verified at individual selected frequencies, to determine whether they are in the pre-established tolerance ranges. This allows, for example, the erroneous detection of a polarization change in one or more microphones.

In addition, it is possible to evaluate the travel times. For this purpose, one transforms the transfer function by discrete Fourier transformation (DFT) into the time domain, and thus one obtains the impulse response of the entire electro-acoustical four-pole loudspeaker-microphone-filter.

From the impulse responses of the individual microphone-filter pairs, the corresponding travel time can easily be ascertained by determining the absolute maximum of the impulse responses. The travel times of the individual microphone-filter pairs now must assume certain precalculated values as a function of the loudspeaker-microphone separation and as a function of the speed of sound in air. In particular, this makes it possible to determine whether individual microphones have been switched or whether the sequence of the microphones has been reversed by mistake.

1. Array microphone with several individual microphones (1-4) connected with a signal processor (11) that comprises at least one digital filter for each individual microphone, in particular for voice recognition, characterized in that at least one loudspeaker (5) is provided, which is arranged in the acquisition area of each of the individual microphones (1-4), that an electronic circuit is provided, which applies a signal to the loudspeaker (5) in such a manner that it emits a predetermined periodic noise signal, and that the signal processor (11) evaluates the response signals coming from each of the microphones and/or from each of the digital filters as a response to the reception of the periodic noise signal.

2. Method for checking array microphones, comprising several individual microphones (1-4) connected with a signal processor (11), that comprises at least one digital filter for each individual microphone, characterized in that at least one loudspeaker (5) is provided in the acquisition area of each of the individual microphones (1-4) and connected with a signal processor (11), to which each microphone (1-4) is also connected, and that the signal processor (11) emits a predetermined periodic noise signal via the loudspeaker (5), that the signal processor (11) evaluates the response signals that subsequently come from each individual microphone (1-4) and/or from each of the digital filters, and compares them with model signals stored in the signal processor (11) or externally, and which correspond to properly operating individual microphones (1-4) or properly operating filters, and that the signal processor (11) provides a display in the form of a message and/or stores the deviation of the response signals from the model signals.

3. Method according to claim 2, characterized in that the signal processor (11), before emitting a predetermined periodic noise signal via the loudspeaker (5), carries out a verification of the loudspeaker (5), where the loudspeaker signal is directly applied to the A/D converter (9) and said loudspeaker is operated in parallel to the input impedance of the A/D converter (9), and where the loudspeaker (5), together with the output resistance of the output amplifier (7) which operates the loudspeaker (5), forms a voltage divider, and that the signal applied to the A/D converter (9) is recorded and evaluated by comparing this signal with a reference signal that originates from the measurement with a reference impedance instead of the loudspeaker impedance.

4. Method according to claim 3, characterized in that the ratio of the loudspeaker impedance to the input impedance of the A/D converter (9) is verified and, if it deviates too far from the value of 1, is adjusted by an additional pre-resistance, which is switched in front of the loudspeaker (5).

5. Method for the automatic calibration of array microphones, comprising several individual microphones (1-4) connected to a signal processor (11) that comprises at least one digital filter for each individual microphone, whereby the signal processor (11) increases the bundling degree of the array microphone and suppresses lateral sound sources by means of an appropriate algorithm applied to the individual microphone signals, whereby filter coefficient sets used in the digital filters and which are characteristic for the arrangement, type, sensitivity, and characteristics of the used individual microphones (1-4), the acoustical environment, and the location of the sound sources are components of the algorithm, characterized in that at least one loudspeaker (5) is provided in the acquisition area of each individual microphone (1-4), which loudspeaker is connected with a signal processor (11), to which each individual microphone (1-4) is also connected, in that the signal processor (11) emits via the loudspeaker (5), a predetermined periodic noise signal, that the signal processor (11) evaluates the response signals that subsequently come from each individual microphone (1-4) and/or from each digital filter and compares them with model signals which are stored in the signal processor (11), or externally, and which correspond to properly operating individual microphones (1-4) or properly operating digital filters, and that the signal processor (11), as a function of the deviation of the response signals from the model signals, changes the value of individual filter coefficients or of all the filter coefficients of the filter coefficient set and repeats the test until the response signals are in the range of the model signals.

6. Method according to claim 5, characterized in that, after a predetermined number of test repetitions have been carried out, the test is interrupted and an error message is displayed and/or stored.
